(19) United States
(12) Patent Application Publication
(10) Pub. No.: US 2009/0097215 A1
(43) Pub. Date: Apr. 16, 2009

(54) UV-EPOXY AND ULTRASONIC CASE ASSEMBLY METHODS FOR USB FLASH DRIVE

(76) Inventors: Siew S HIEW, San Jose, CA (US); Nan Nan, San Jose, CA (US); Jim Ni, San Jose, CA (US); Ming-Shiang Shen, Taipei Hsien (TW)

Correspondence Address: SINORICA, LLC, 528 FALLSGROVE DRIVE, ROCKVILLE, MD, 20850, US

(21) Appl. No.: 11/870,435

(22) Filed: Oct. 11, 2007

(51) Int. Cl. H05K 5/00

(52) U.S. Cl. 361/757

(57) ABSTRACT

The present invention discloses UV-epoxy and ultrasonic case assembly methods for a USB flash drive, wherein a transparent or translucent top cover is fastened to a bottom cover containing a printed circuit board assembly via an UV-cure epoxy glue or an ultrasonic weld method. As the top cover of the USB flash drive is transparent or translucent, the USB flash drive has a see-through property and presents an aesthetic taste, which can attract the attention of consumers. Further, the method of the present invention uses less case parts and fewer steps and thus can fabricate a USB flash drive having a lower cost and a better quality at a higher throughput. Furthermore, the USB flash drive fabricated according to the method of the present invention has a better moisture resistance and a better water resistance.

### BACKGROUND OF THE INVENTION

1. Field of the Invention

The present invention relates to alternative case assembly methods for a USB flash drive, particularly to UV-epoxy and ultrasonic case assembly methods for a USB flash drive.

2. Description of the Related Art

With advance of semiconductor technology and population of computers, accessory memory devices also develop explosively. They are usually featherweight and thumb-sized USB flash drives.

Confronting so many brands of USB flash drives in markets, a manufacturer must outstand his quality and design, improve his efficiency and reduce his cost to achieve his competitiveness.

The chips and electronic elements on the printed circuit board of a USB flash drive and the printed circuit board itself are apt to be damaged by moisture and water.

The case of a USB flash drive usually has an upper cover and a lower cover assembled together via various assembly methods. However, the conventional assembly methods usually need more than two pieces of casing components, which results in a more complicated assembly process and a higher cost.

Besides, the conventional assembly methods for a USB flash drive often result in insufficient moisture and water resistance.

Therefore, the present invention proposes novel case assembly methods for a USB flash drive to overcome the abovementioned problems, wherein UV-cure epoxy or ultrasonic vibration is used to assemble a flash drive case which needs only two pieces of covers, whereby the assembly process is simplified, the assembly speed is increased, and the cost of a flash drive is reduced.

### SUMMARY OF THE INVENTION

One objective of the present invention is to provide a UV (Ultra-Violet)-epoxy case assembly method for a USB (Universal Serial Bus) flash drive, wherein UV-cure epoxy is used to bond a UV-permeable top/bottom cover to a bottom/top cover to form a USB flash drive.

Another objective of the present invention is to provide an ultrasonic case assembly method for a USB flash drive, wherein ultrasonic vibration is used to weld a top cover to a bottom cover to form a USB flash drive.

Yet another objective of the present invention is to provide a case assembly method for a USB flash drive, which can fabricate a USB flash drive having a better moisture resistance and a better water resistance.

Still another objective of the present invention is to provide a case assembly method for a USB flash drive, which uses less case parts and fewer steps and thus can fabricate a USB flash drive having a lower cost and a better quality at a higher throughput.

Further another objective of the present invention is to provide a case assembly method for a USB flash drive, which can fabricate a USB flash drive having a see-through property.

To achieve the abovementioned objectives, the present invention proposes a UV-epoxy case assembly method for a USB flash drive, which comprises steps: providing a bottom cover; placing a printed circuit board assembly into the cavity of the bottom cover; dispensing a UV-cure epoxy glue onto the edge surface of the bottom cover; aligning and gluing a UV-permeable top cover to the bottom cover to form a glued package; and placing the glued package under a UV light source to cure the UV-cure epoxy glue and complete a USB flash drive. Alternatively, the bottom cover is made of a UV-permeable material, and the top cover is not limited to a UV-permeable cover but may also be an opaque cover.

The present invention also proposes an ultrasonic case assembly method for a USB flash drive, which comprises steps: providing a bottom cover; placing a printed circuit board assembly into the cavity of the bottom cover; aligning a top cover to the bottom cover to form a package; and placing the package in an ultrasonic vibration press machine to weld the top cover to the bottom cover and complete a USB flash drive.

Below, the embodiments will be described in detail in cooperation with the attached drawings to make easily understood the objectives, technical contents, characteristics and accomplishments of the present invention.

### BRIEF DESCRIPTION OF THE DRAWINGS

FIG. 1 to FIG. 4 are diagrams schematically showing the steps of a UV-epoxy case assembly method for a USB flash drive according to a first embodiment of the present invention;

FIG. 5 is a diagram schematically showing that the top cover has a contour exactly identical to that of the bottom cover according to the present invention;

FIG. 6 is a diagram schematically showing that the top cover only covers the wider portion of the PCBA according to the present invention;

FIG. 7 is a flowchart of a UV-epoxy case assembly method for a USB flash drive according to the first embodiment of the present invention;

FIG. 8 to FIG. 10 are diagrams schematically showing the steps of an ultrasonic case assembly method for a USB flash drive according to a second embodiment of the present invention.

FIG. 11 is a flowchart of an ultrasonic case assembly method for a USB flash drive according to a second embodiment of the present invention.

### DETAILED DESCRIPTION OF THE INVENTION

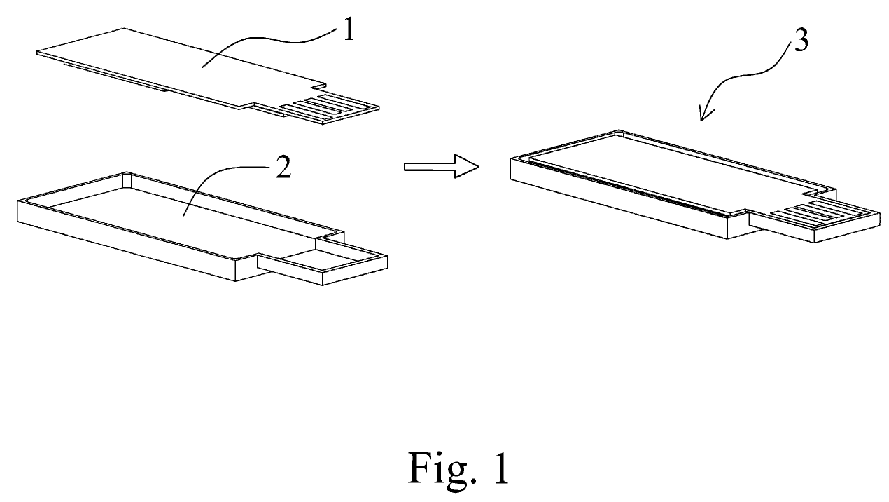

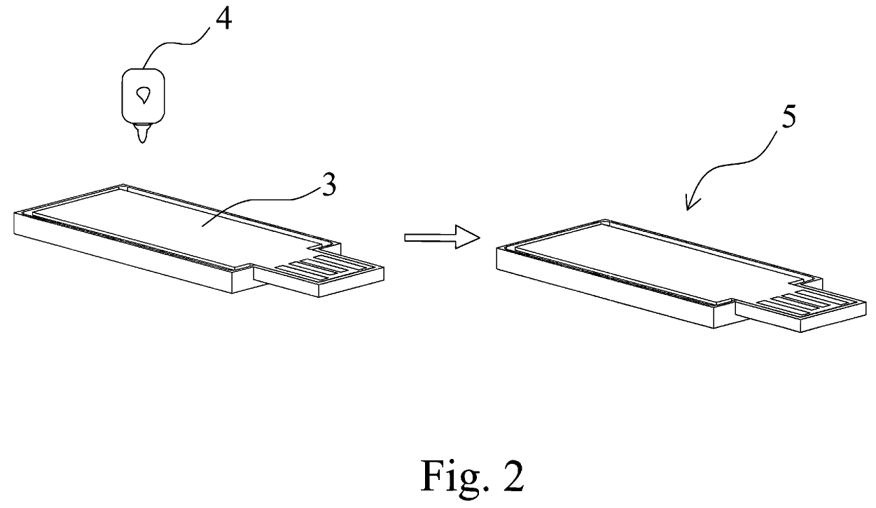

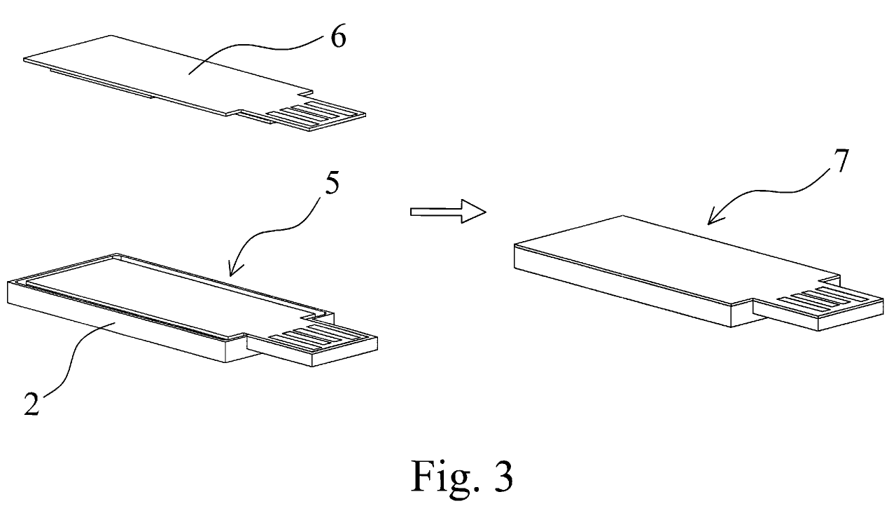

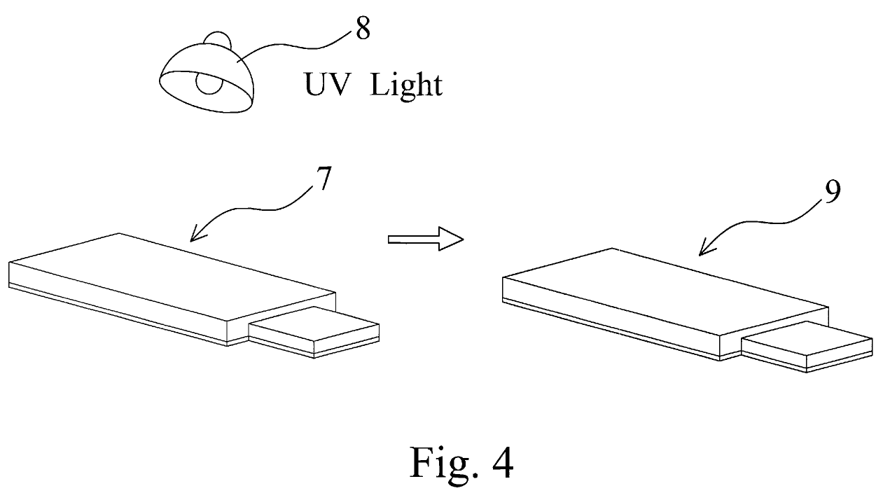

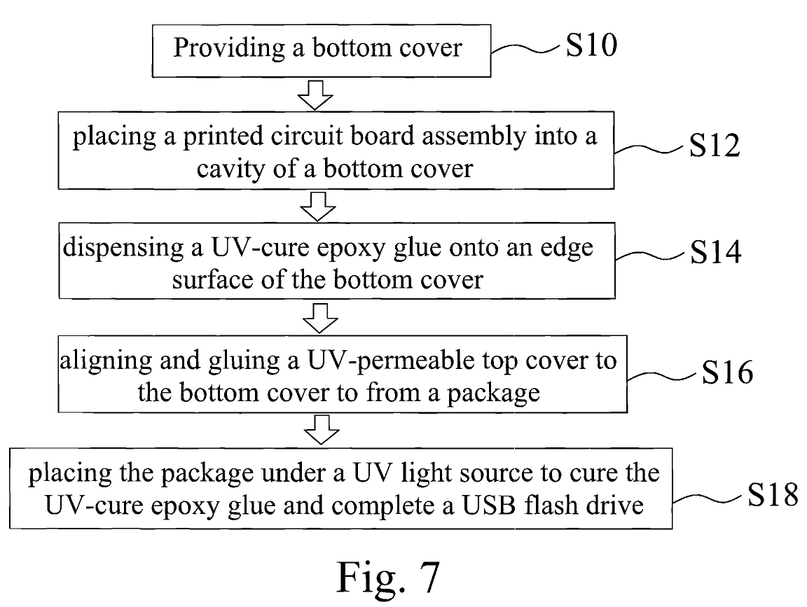

Refer to from FIG. 1 to FIG. 4 diagrams schematically showing the steps of a method according to a first embodiment of the present invention. Refer to FIG. 7, a flowchart of the method according to the first embodiment of the present invention. In Step S10, a bottom cover 2 is provided; the bottom cover 2 is made of a UV-permeable material, such as a transparent plastic or a translucent plastic; the transparent plastic is a clear plastic or a color-tinted transparent plastic, and the translucent plastic is a color-tinted translucent plastic. In Step S12, a PCBA 1 (Printed Circuit Board Assembly) is placed into the cavity of the bottom cover 2 to form a first sub-assembly 3, as shown in FIG. 1. The PCBA 1 includes: a PCB (Printed Circuit Board), a flash memory chip, a control chip and passive elements. The PCB has a relatively narrow section and a relatively wide section and has a first surface face and a second surface. The connection plug, which has a plurality of gold plated lead fingers for electrical contact, is arranged in the relatively narrow section and on the first surface. IC chips and components are arranged in the relatively wide section and on the second surface. The PCBA 1 is placed into the cavity of the bottom cover 2 with the second surface having the IC chips and components faced downward. In Step S14, an UV-cure epoxy glue 4 is dispensed onto the edge surface of the bottom cover 2 with an epoxy dispensing machine to form a second sub-assembly 5, as shown in FIG. 2. In Step S16, a top cover 6 is aligned and glued to the bottom cover 2 of the second sub-assembly 5 to form a third sub-assembly 7, as shown in FIG. 3. The top cover 6 may be a color-tinted opaque, transparent or translucent plastic or a clear plastic. In Step S18, the third sub-assembly 7 is placed under a UV light source 8 to cure the UV-cure epoxy glue 4 and complete a USB flash drive 9, as shown in FIG. 4.

Alternatively, the top cover 6 may be limited to be a color-tinted transparent or translucent plastic or a clear plastic, and the bottom cover 2 may be a color-tinted opaque, transparent or translucent plastic or a clear plastic.

In the first embodiment, as at least one cover of the USB flash drive 9 is transparent or translucent, the USB flash drive 9 has a see-through property. The internal view of the USB flash drive 9, such as the PCB, chips, and elements (e.g. a LED indicator), can been seen from the outside. The internal view and LED lights through transparent or translucent tints will present an aesthetic taste and attract consumers.

In the first embodiment, the top cover 6 and the bottom cover 2 are fabricated into intended shapes and right dimensions with an automatic molding method, such as the mold injection technology.

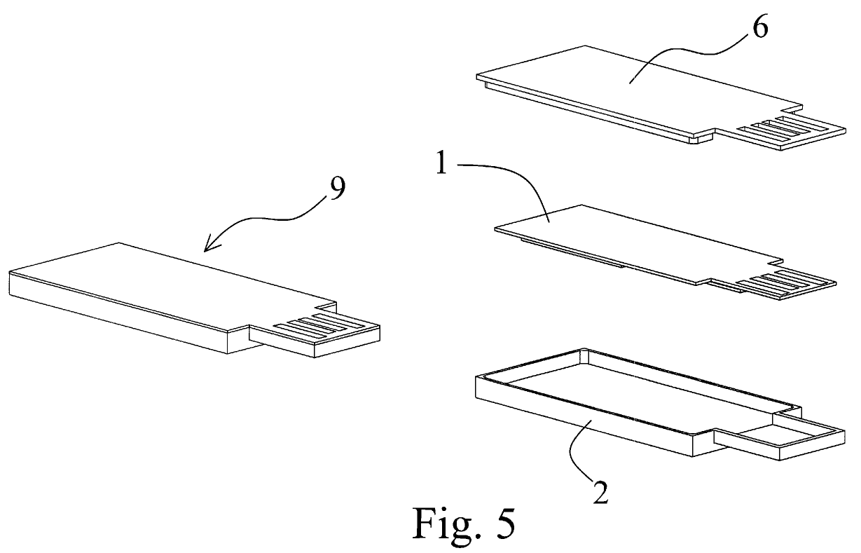

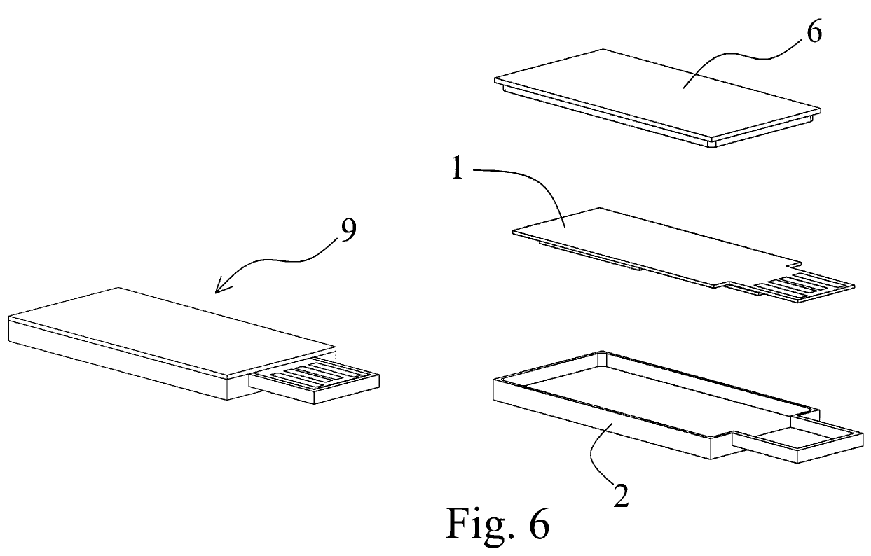

In the first embodiment, the top cover 6 may have a contour exactly the same as the bottom cover 2, as shown in FIG. 5. Alternatively, the top cover 6 may only cover the wider portion of the PCBA 1, as shown in FIG. 6.

The first embodiment can apply to both the slim profile type of USB flash drive and the standard full thickness type of USB flash drive.

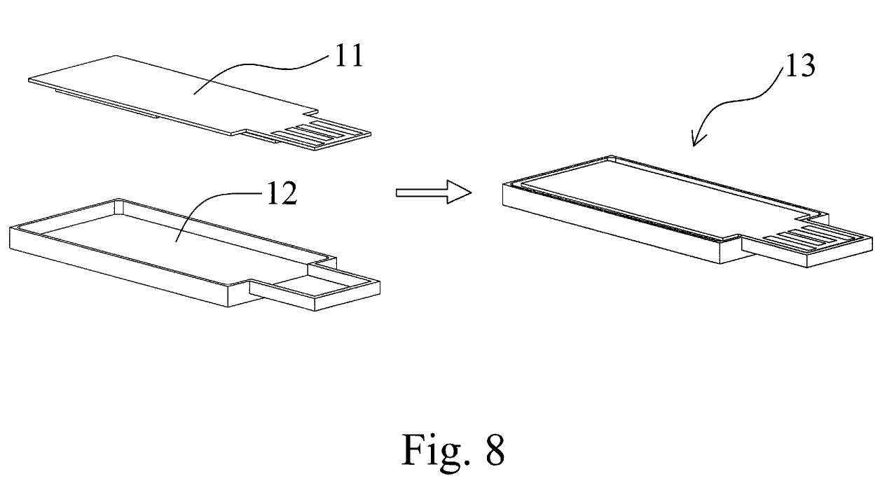

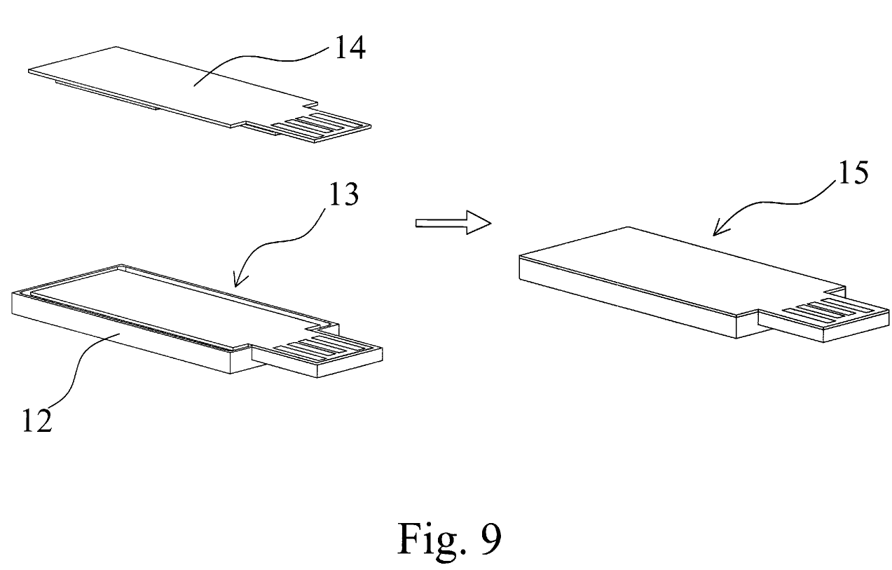

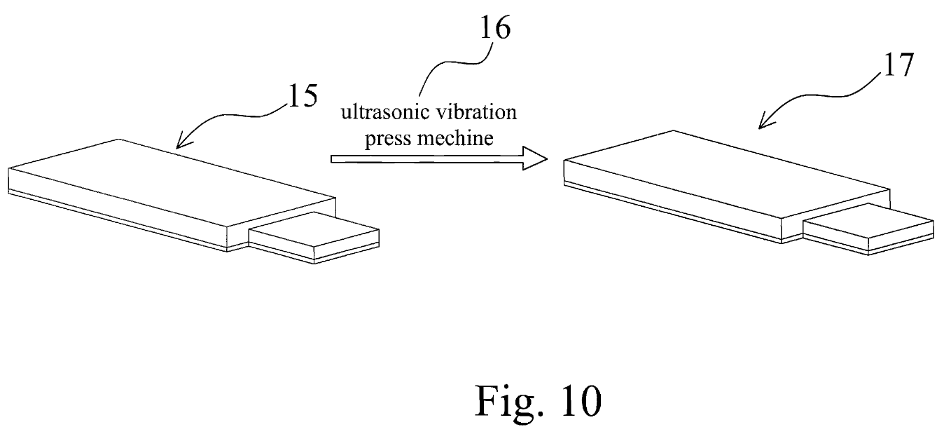

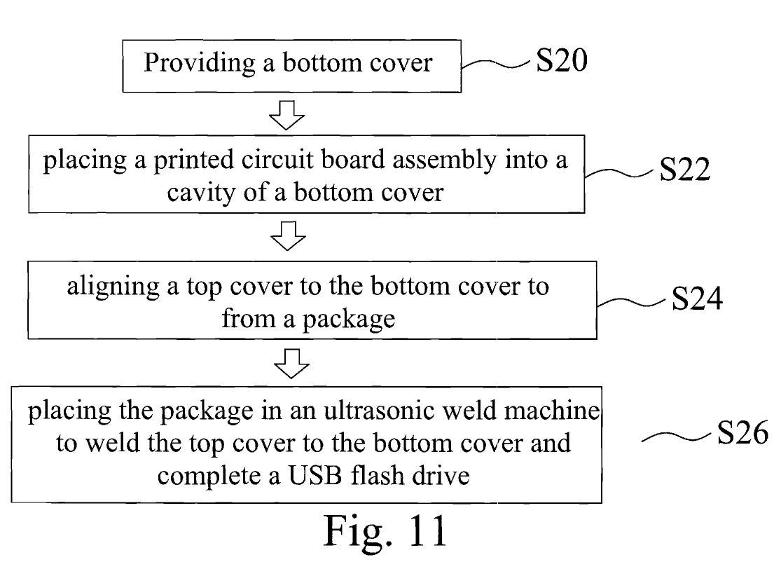

Refer to from FIG. 8 to FIG. 10 diagrams schematically showing the steps of a method according to a second embodiment of the present invention. Refer to FIG. 11 a flowchart of the method according to the second embodiment of the present invention. In Step S20, a bottom cover 12 is provided; the bottom cover 12 is made of an opaque plastic, a transparent plastic or a translucent plastic; the opaque plastic is a color-tinted opaque plastic; the transparent plastic is a clear plastic or a color-tinted transparent plastic; and the translucent plastic is a color-tinted translucent plastic. In Step S22, a PCBA 11 (Printed Circuit Board Assembly) is placed into the cavity of the bottom cover 12 to form a first sub-assembly 13, as shown in FIG. 8. The PCBA 11 is similar to the PCBA 1 described in the first embodiment. In Step S24, a top cover 14 is aligned and secured to the bottom cover 12 of the first sub-assembly 13 to form a second sub-assembly 15, as shown in FIG. 9. The top cover 14 may be a color-tinted opaque, transparent or translucent plastic or a clear plastic. In Step S26, the second sub-assembly 15 is placed in an ultrasonic vibration press machine 16 to weld the top cover 14 to the bottom cover 12 and complete a USB flash drive 17, as shown in FIG. 10.

In the second embodiment, one cover or both covers of the USB flash drive 17 may be transparent or translucent, and the USB flash drive 17 may have a see-through property. Thus, the internal view of the USB flash drive 17, such as the PCB, chips, and elements (e.g. a LED indicator), can been seen from the outside.

In the second embodiment, the top cover 14 and the bottom cover 12 are fabricated into intended shapes and right dimensions with an automatic molding method, such as the mold injection technology.

In the second embodiment, the top cover 14 may have a contour exactly the same as the bottom cover 12. Alternatively, the top cover 14 may only cover the wider portion of the PCBA 11.

The second embodiment can apply to both the slim profile type of USB flash drive and the standard full thickness type of USB flash drive.

In conclusion, the present invention proposes UV-epoxy and ultrasonic case assembly methods for a USB flash drive, wherein a top cover is fastened to a bottom cover containing a printed circuit board assembly via an UV-cure epoxy glue or an ultrasonic weld method, and wherein at least one of the top and bottom covers is transparent or translucent. As the method of the present invention uses less case parts and fewer steps, it can fabricate a USB flash drive having a lower cost and a better quality at a higher throughput. As at least one of the top and bottom covers of the USB flash drive is transparent or translucent, the USB flash drive has a see-through property and presents an aesthetic taste, which can attract the attention of consumers. Further, the USB flash drive fabricated according to the method of the present invention has a better moisture resistance and a better water resistance.

Those described above are only the embodiments to exemplify the present invention but not to limit the scope of the present invention. Any equivalent modification or variation according to the shapes, structures, characteristics or spirit disclosed in the present invention is to be also included within the scope of the present invention.

What is claimed is:

1. A case assembly method for a USB (Universal Serial Bus) flash drive comprising steps:
providing a bottom cover;
placing a printed circuit board assembly into a cavity of said bottom cover;
dispensing a UV (Ultra-Violet)-cure epoxy glue onto an edge surface of said bottom cover;
aligning and gluing a UV-permeable top cover to said bottom cover to form a package; and
placing said package under a UV light source to cure said UV-cure epoxy glue and complete a USB flash drive.

2. The case assembly method for a USB flash drive according to claim 1, wherein said top cover is made of a clear plastic, a color-tinted opaque plastic, a color-tinted transparent plastic or a color-tinted translucent plastic.

3. The case assembly method for a USB flash drive according to claim 1, wherein said bottom cover is made of a clear plastic, a color-tinted opaque plastic, a color-tinted transparent plastic or a color-tinted translucent plastic.

4. The case assembly method for a USB flash drive according to claim 1, wherein said bottom cover is made of a UV-permeable material, and said top cover is not limited to a UV-permeable top cover but is an opaque top cover.

5. The case assembly method for a USB flash drive according to claim 4, wherein said top cover is made of a clear plastic, a color-tinted opaque plastic, a color-tinted transparent plastic or a color-tinted translucent plastic; and said bottom cover is made of a clear plastic, a color-tinted transparent plastic or a color-tinted translucent plastic.

6. The case assembly method for a USB flash drive according to claim 1, wherein said top cover and said bottom cover are respectively fabricated into intended shapes and right dimensions with an automatic molding method.

7. The case assembly method for a USB flash drive according to claim 6, wherein said automatic molding method is a mold injection technology.

8. The case assembly method for a USB flash drive according to claim 1, wherein said top cover has a contour exactly identical to that of said bottom cover.

9. The case assembly method for a USB flash drive according to claim 1, wherein said top cover only covers a wider portion of said printed circuit board assembly.

10. The case assembly method for a USB flash drive according to claim 1, wherein said UV-cure epoxy glue is dispensed with an epoxy dispensing machine.

11. The case assembly method for a USB flash drive according to claim 1, which apply to a slim profile type of USB flash drive and a standard full thickness type of USB flash drive.

12. A case assembly method for a USB (Universal Serial Bus) flash drive comprising steps:
providing a bottom cover;
placing a printed circuit board assembly into a cavity of said bottom cover;
aligning a top cover to said bottom cover to form a package; and
placing said package in an ultrasonic weld machine to weld said top cover to said bottom cover and complete a USB flash drive.

13. The case assembly method for a USB flash drive according to claim 12, wherein said top cover is made of a clear plastic, a color-tinted transparent plastic, a color-tinted translucent plastic or a color-tinted translucent plastic.

14. The case assembly method for a USB flash drive according to claim 12, wherein said bottom cover is made of a clear plastic, a color-tinted opaque plastic, a color-tinted transparent plastic or a color-tinted translucent plastic.

15. The case assembly method for a USB flash drive according to claim 12, wherein said top cover and said bottom cover are respectively fabricated into intended shapes and right dimensions with an automatic molding method.

16. The case assembly method for a USB flash drive according to claim 15, wherein said automatic molding method is a mold injection technology.

17. The case assembly method for a USB flash drive according to claim 12, wherein said top cover has a contour exactly identical to that of said bottom cover.

18. The case assembly method for a USB flash drive according to claim 12, wherein said top cover only covers a wider portion of said printed circuit board assembly.

19. The case assembly method for a USB flash drive according to claim 12, wherein said top cover is welded to said bottom cover with an ultrasonic vibration press machine.

20. The case assembly method for a USB flash drive according to claim 12, which apply to a slim profile type of USB flash drive and a standard full thickness type of USB flash drive.
